(19) United States
(12) Patent Application Publication
(10) Pub. No.: US 2003/0168169 A1
(43) Pub. Date: Sep. 11, 2003

(54) Chemical-mechanical polishing apparatus, polishing pad and method for manufacturing semiconductor device

(76) Inventors: Akira Ishikawa, Kawasaki-shi (JP); Satoru Ide, Ammaka-shi (JP); Eiichi Yamamoto, Isehara-shi (JP); Kiyoshi Tanaka, Tokyo (JP); Takahiko Mitsui, Annaka-shi (JP)

Correspondence Address: MORGAN LEWIS & BOCKIUS LLP, 1111 PENNSYLVANIA AVENUE NW, WASHINGTON, DC, 20004, US

(21) Appl. No.: 10/343,434

(22) PCT Filed: Feb. 1, 2001
(86) PCT No.: PCT/JP01/00693

(30) Foreign Application Priority Data
Aug. 3, 2000 (JP) 2000-235590

(51) Int. Cl. C23F 1/00; H01L 21/302

(52) U.S. Cl. 156/345.12

(57) ABSTRACT

The present invention is a chemical mechanical polishing apparatus which polishes a substrate by causing relative movement of this substrate and a polishing pad in a state in which a polishing liquid is interposed between this polishing pad and the substrate, wherein the shape of the above-mentioned polishing pad is an annular shape in which the central portion of a circle or ellipse is bored through in a circular or elliptical shape that has a smaller diameter. The internal diameter li of the hole that is bored through the annular polishing pad is 5 to 75%, preferably 30 to 50%, of the external diameter lo of the polishing pad.

The ratio of the external diameter of the polishing pad to the external diameter of the substrate w with the metal film that is being polished is 0.5 to 0.75 times in the case of a circular annular pad; in the case of an elliptical annular pad, this ratio is 0.35 to 0.40 times for the short-axis diameter, and 0.5 to 0.75 times for the long-axis diameter.

### TECHNICAL FIELD

The present invention relates to a chemical mechanical polishing apparatus which makes it possible to manufacture substrates in which the uniformity of the thickness distribution of the substrate is superior, and also relates to a polishing pad and a semiconductor device manufacturing method using the above-mentioned chemical mechanical polishing apparatus.

### BACKGROUND ART

Polishing apparatuses are known in which wafers are subjected to polishing or CMP polishing (chemical mechanical polishing or chemical mechanical planarization) by using a polishing pad that is shaft-supported on a spindle shaft, pressing a wafer that is held in a chuck against the surface of the above-mentioned polishing pad while supplying a polishing material slurry to this surface, and causing the pad and wafer to rotate in the same direction or in opposite directions (Japanese Patent Application Kokai No. H6-21028, Japanese Patent Application Kokai No. H7-266219, Japanese Patent Application Kokai No. H8-192353, Japanese Patent Application Kokai No. H8-293477, Japanese Patent Application Kokai No. H10-173715, Japanese Patent Application Kokai No. H11-156711 and British Laid-Open Patent No. 2331948, etc.).

Pad materials that are used include hard foam urethane sheets, polyester fiber nonwoven fabrics, felt, polyvinyl alcohol fiber nonwoven fabrics, nylon fiber nonwoven fabrics, and materials in which a foaming urethane resin solution is flow-spread on such nonwoven fabrics, and is then foamed and hardened, etc.

Conventionally, the pad shape has been circular, like the shape of the substrate that is being polished, and pads with a thickness of 1 to 7 mm have been used in a configuration in which these pads are pasted to an attachment plate such as an aluminum plate or stainless steel plate.

As is indicated, for example, in Japanese Patent Application Kokai No. H10-173715 and Japanese Patent Application Kokai No. H11-156711, in order to subject substrates with metal films to CMP polishing using such circular pads, chemical mechanical polishing has conventionally been performed by a process in which the substrate that has a metal film is held on a chucking table with the metal film surface facing upward, the surface of a polishing pad pasted on an attachment plate which is shaft-supported on a spindle shaft that has a shaft core oriented in the vertical direction is pressed against the above-mentioned substrate in relative terms with free polishing abrasive grains interposed, the substrate and polishing pad are caused to rub and slide against each other, and the polishing pad is caused to swing back and forth in the left-right direction for a distance of 20 to 50 mm on the surface of the substrate, so that at least a portion of the metal film on the surface of the substrate is removed.

The diameter of this polishing pad is approximately ½ of the diameter of the substrate that has a metal film. Polishing is accomplished by causing the polishing pad to swing back and forth in the left-right direction for a distance of 20 to 50 mm on the surface of the substrate and causing the pad to rotate at a high speed of 150 to 800 rpm, so that the high-speed working required in the CMP polishing of a substrate with a diameter of 300 mm can be accomplished. However, the dishing of the metal layer on a substrate obtained as a result of such high-speed polishing is large, i.e., 200 to 320 nm, and erosion also reaches a large value of 60 to 100 nm if the density of the metal film with respect to the insulating layer is large. Accordingly, in device wafers, there is a demand from the marketplace for a reduction of dishing to 60 nm or less and a reduction of erosion to 80 nm or less in the case of applications involving a high degree of integration, i.e., 5 to 10 device layers.

### DISCLOSURE OF THE INVENTION

One object of the present invention is to provide a chemical mechanical polishing apparatus which polishes a substrate by causing relative movement of this substrate and a polishing pad in a state in which a polishing liquid is interposed between this polishing pad and the substrate, so that the above-mentioned market demand is satisfied.

Furthermore, another object of the present invention is to provide a polishing pad which is used in the above-mentioned chemical mechanical polishing apparatus, and which satisfies the above-mentioned market demand.

Furthermore, another object of the present invention is to provide a semiconductor device manufacturing method which achieves an increase in the yield by satisfying market demands relating to dishing and erosion in polishing processes, and which thus makes it possible to manufacture semiconductor devices at a lower cost than is possible in conventional semiconductor device manufacturing methods.

The content of the present invention will be described below.

The invention described in claim 1 is a chemical mechanical polishing apparatus which polishes a substrate by causing relative movement of this substrate and a polishing pad in a state in which a polishing liquid is interposed between this polishing pad and the substrate, wherein the shape of the above-mentioned polishing pad is an annular shape in which the central portion of a circle or ellipse is bored through in a circular or elliptical shape that has a smaller diameter.

In this invention, as a result of chemical mechanical polishing being performed using an annular polishing pad whose central portion is bored through, dishing and erosion can be reduced even in high-speed polishing processes.

The invention described in claim 2 is a chemical mechanical polishing apparatus in which a substrate that has a metal film is held on a chucking table with the metal film surface facing upward, the surface of a polishing pad pasted on an attachment plate which is shaft-supported on a spindle shaft that has a shaft core oriented in the vertical direction is pressed against the above-mentioned substrate in relative terms with free polishing abrasive grains interposed, and the substrate and polishing pad are caused to rub and slide against each other so that at least a portion of the metal film on the surface of the substrate is removed, wherein this apparatus comprises a raising-and-lowering mechanism for the above-mentioned polishing pad, and a feeding mechanism that causes the above-mentioned polishing pad to perform a reciprocating motion in the left-right direction, the shape of the above-mentioned polishing pad is an annular shape in which the central portion of a circle or ellipse is bored through in a circular or elliptical shape that has a smaller diameter, and the diameter of the polishing pad is smaller than the diameter of the substrate.

In this invention, since chemical mechanical polishing is performed using an annular polishing pad in which the central portion of the pad is bored through, and since this polishing is performed while causing the polishing pad to perform a reciprocating motion in the left-right direction, dishing can be reduced to 60 nm or less, and erosion can be suppressed to 80 nm or less, even in high-speed polishing processes.

The invention described in claim 3 is a chemical mechanical polishing apparatus in which an STI substrate that has a P-TEOS film is held on a chucking table with the P-TEOS film surface facing upward, the surface of a polishing pad pasted on an attachment plate which is shaft-supported on a spindle shaft that has a shaft core oriented in the vertical direction is pressed against the above-mentioned substrate in relative terms with free polishing abrasive grains interposed, and the substrate and polishing pad are caused to rub against each other so that at least a portion of the P-TEOS film on the surface of the substrate is removed, wherein this apparatus comprises a raising-and-lowering mechanism for the above-mentioned polishing pad, and a feeding mechanism that causes the above-mentioned polishing pad to perform a reciprocating motion in the left-right direction, the shape of the above-mentioned polishing pad is an annular shape in which the central portion of a circle or ellipse is bored through in a circular or elliptical shape that has a smaller diameter, and the diameter of the polishing pad is smaller than the diameter of the substrate.

The invention described in claim 4 is a chemical mechanical polishing apparatus in which a substrate that has an insulating layer film formed on top of a metal film pattern is held on a chucking table with the insulating layer film surface facing upward, the surface of a polishing pad pasted on an attachment plate which is shaft-supported on a spindle shaft that has a shaft core oriented in the vertical direction is pressed against the above-mentioned substrate in relative terms with free polishing abrasive grains interposed, and the substrate and polishing pad are caused to rub against each other so that at least a portion of the insulating layer film on the surface of the substrate is removed, wherein this apparatus comprises a raising-and-lowering mechanism for the above-mentioned polishing pad, and a feeding mechanism that causes the above-mentioned polishing pad to perform a reciprocating motion in the left-right direction, the shape of the above-mentioned polishing pad is an annular shape in which the central portion of a circle or ellipse is bored through in a circular or elliptical shape that has a smaller diameter, and the diameter of the polishing pad is smaller than the diameter of the substrate.

In the invention described in claim 3 and the invention described in claim 4, dishing and erosion can be suppressed not only in the removal of a metal film, but also in the removal of an insulating layer or removal of a P-TEOS film on an STI.

The invention described in claim 5 is an y of the inventions described in claim 2 through claim 4, wherein the above-mentioned feeding mechanism has the function of varying the movement speed of the above-mentioned polishing pad in the left-right direction in accordance with the position of the above-mentioned polishing pad with respect to the above-mentioned substrate.

In this invention, dishing and erosion can be suppressed more effectively.

The invention described in claim 6 is a chemical mechanical polishing apparatus in which a substrate whose maximum external diameter is approximately the same as or smaller than the maximum external diameter of the polishing pad is polished by causing the relative movement of the above-mentioned polishing pad and the above-mentioned substrate in a state in which a polishing liquid is interposed between the above-mentioned polishing pad and the above-mentioned substrate wherein the shape of the above-mentioned polishing pad has an annular shape.

The invention described in claim 7 is the chemical mechanic al polishing apparatus described in claim 6, wherein the shape of the above-mentioned polishing pad is an annular shape in which the central portion of a circle or ellipse is bored through in a circular or elliptical shape that has a smaller diameter.

In these inventions described in claim 6 and claim 7, since chemical mechanical polishing is performed using an annular polishing pad, dishing and erosion can be suppressed even in high-speed polishing processes.

The invention described in claim 8 is any of the inventions described in claim 1 through claim 7, wherein the internal diameter of the hole that is bored through the above-mentioned polishing pad is 5 to 75% of the external diameter of the above-mentioned polishing pad.

In this invention, dishing and erosion can be effectively suppressed as a result of the proportion of the above-mentioned polishing pad that is bored through being set at the above-mentioned value.

The invention described in claim 9 is a polishing pad which has an annular shape, and whose maximum dimension is approximately the same as or smaller than the maximum dimension of the substrate that is polished.

The invention described in claim 10 is the polishing pad described in claim 9, wherein the shape of this polishing pad is an annular shape in which the central portion of a circle or ellipse is bored through in a circular or elliptical shape that has a smaller diameter.

By using the polishing pad described in claim 9 or claim 10, it is possible to suppress dishing and erosion in a chemical mechanical polishing apparatus, even in the case of high-speed polishing.

The invention described in claim 11 is the polishing pad described in claim 10, wherein the diameter of the above-mentioned portion that is bored through is 5 to 75% of the external diameter of the above-mentioned polishing pad.

In this invention, dishing and erosion can be effectively suppressed as a result of the proportion of the above-mentioned polishing pad that is bored through being set at the above-mentioned value.

The invention described in claim 12 is a semiconductor device manufacturing method comprising a process in which the surface of a semiconductor wafer is planarized using the chemical mechanical polishing apparatus of any of the inventions described in claim 1 through claim 8.

Market requirements relating to dishing and erosion can be satisfied by using the chemical mechanical polishing apparatus of any of the inventions described in claim 1 through claim 8 in CMP processes; accordingly, the yield can be improved, and as a result, semiconductor devices can be manufactured at a lower cost than is possible in conventional semiconductor device manufacturing methods.

As was described above, dishing and erosion can be suppressed by performing chemical mechanical polishing using a polishing apparatus equipped with the annular polishing pad of the present invention or the polishing apparatus of the present invention, so that device wafers with superior uniformity of the pattern thickness can be obtained. Furthermore, dishing and erosion can be further suppressed by performing chemical mechanical polishing with the speed at which the polishing pad swings in the left-right direction over the substrate (which has a metal film formed on the insulating layer) varied according to the position of the polishing pad relative to the substrate.

Furthermore, erosion and dishing can also be suppressed in the removal of the insulating layer film from a substrate that has an insulating layer film formed on top of a metal pattern, and in the removal of the P-TEOS film layer from an STI.

Furthermore, the present invention can provide a semiconductor device manufacturing method which achieves an increase in the yield by satisfying market requirements relating to dishing and erosion in CMP processes, and which therefore makes it possible to manufacture semiconductor devices at a lower cost than can be achieved in conventional semiconductor device manufacturing methods.

### BRIEF DESCRIPTION OF THE DRAWINGS

FIG. 1 is a perspective view of the polishing apparatus.

FIG. 2 is a perspective view of the polishing apparatus.

FIG. 3 is a sectional view which shows the positional relationship of the polishing head and the conditioning mechanism.

FIG. 4 is a sectional view of the polishing head.

FIG. 5 is a perspective view of the polishing pad.

FIG. 6 is a flow chart which illustrates the semiconductor device manufacturing process.

FIG. 7 is a graph of the correlation between dishing and the rpm of the polishing pad.

FIG. 8 is a graph of the correlation between erosion and the pattern density of the substrate.

FIG. 9 is a graph of the correlation between dishing and the pattern width of the substrate.

FIG. 10 is a graph of the correlation between erosion and the trench width of the STI.

FIG. 11 is a graph of the correlation between erosion and the trench density of the STI.

### BEST MODE FOR CARRYING OUT THE INVENTION

In order to describe the present invention in greater detail, preferred embodiments of the present invention will be described below with reference to the attached figures. However, it goes without saying that the content of these embodiments does not limit the scope of the present invention.

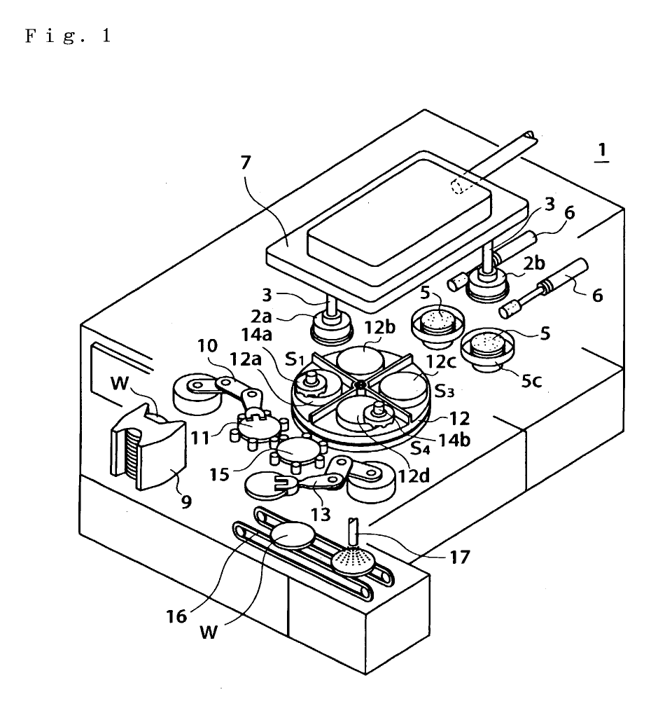

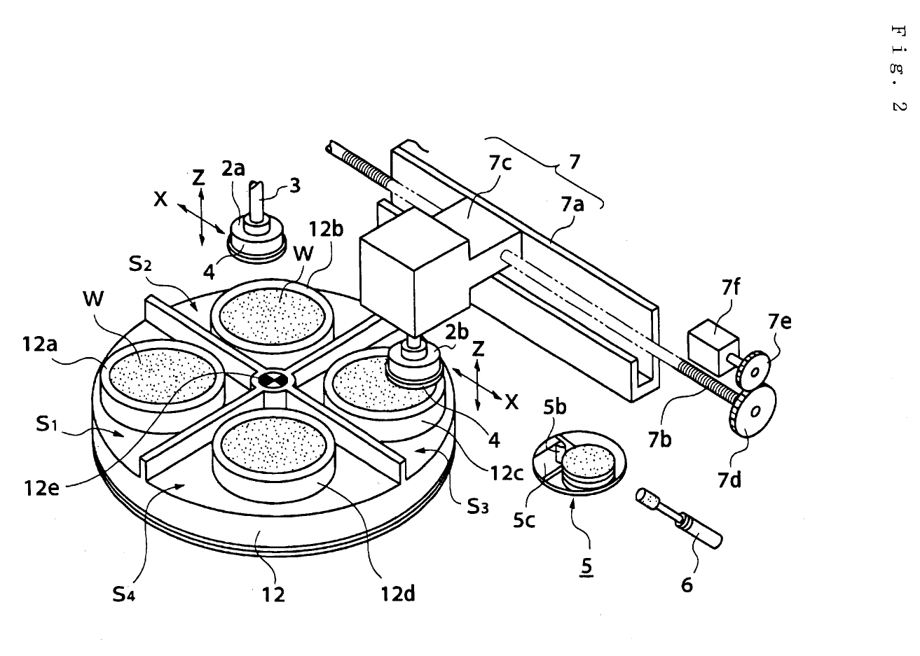

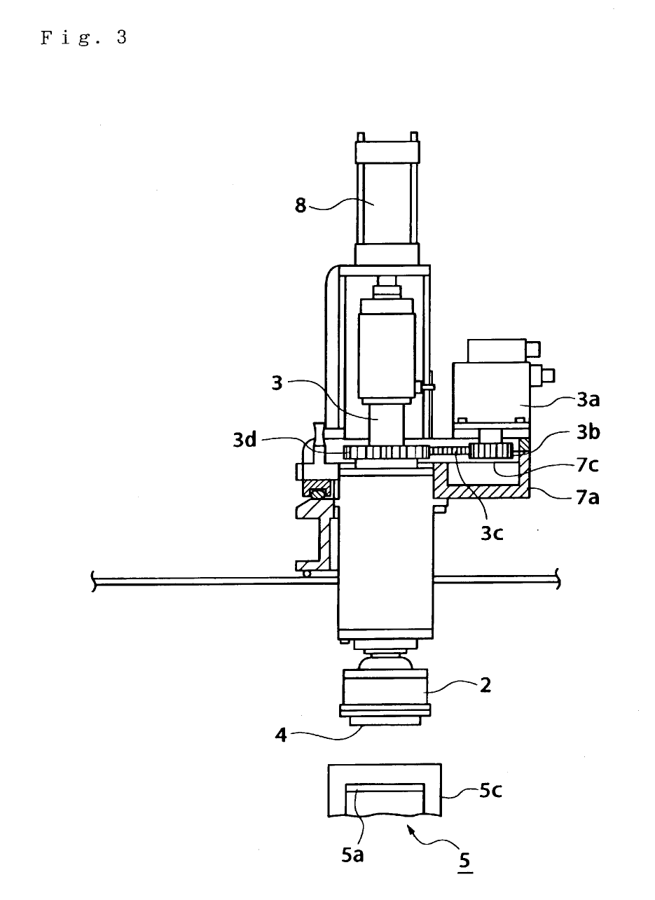

First, an outline of an example of a common chemical mechanical polishing apparatus to which the present invention has been applied will be described with reference to FIGS. 1 through 4.

In the indexing-type chemical mechanical polishing apparatus 1 shown in FIGS. 1, 2 and 3, 2 indicates a polishing head, 2a indicates a polishing head used for rough polishing, 2b indicates a polishing head used for finishing polishing, 3, 3 indicate rotating shafts, 3a indicates a motor, 3b indicates a gear, 3c indicates a pulley, 3d indicates a gear, 4, 4 indicate polishing pads, 5, 5 indicate pad conditioning mechanisms, 5a indicates a dressing disk, 5b indicates a spray nozzle, 5c indicates a protective cover, 6, 6 indicate rotatable cleaning brushes, 7 indicates a feeding mechanism for the polishing head, 7a indicates a rail, 7b indicates a feed screw, and 7c indicates a moving body which is screw-mounted on the feed screw, with the polishing head 2 being mounted on this moving body. 7d and 7e indicate gears, 7f indicates a motor, 8 indicates an air cylinder constituting a head raising-and-lowering mechanism, 9 indicates a cassette that accommodates wafers (substrates) w, 10 indicates a loading-conveying robot, 11 indicates a wafer temporary placement stand, and 12 indicates an indexing table which has four rotatable wafer chucking mechanisms 12a, 12b, 12c and 12d installed at equal intervals on the same circle centered on a shaft 12e. This table 12 is divided into a wafer loading zone s1, a rough polishing zone s2, a wafer finishing polishing zone s3, and a wafer unloading zone s4.

13 indicates an unloading-conveying robot, 14a indicates a chuck dresser, 14b indicates a chuck cleaning mechanism, 15 indicates a wafer temporary placement stand, 16 indicates a belt conveyor, and 17 indicates a wafer cleaning mechanism.

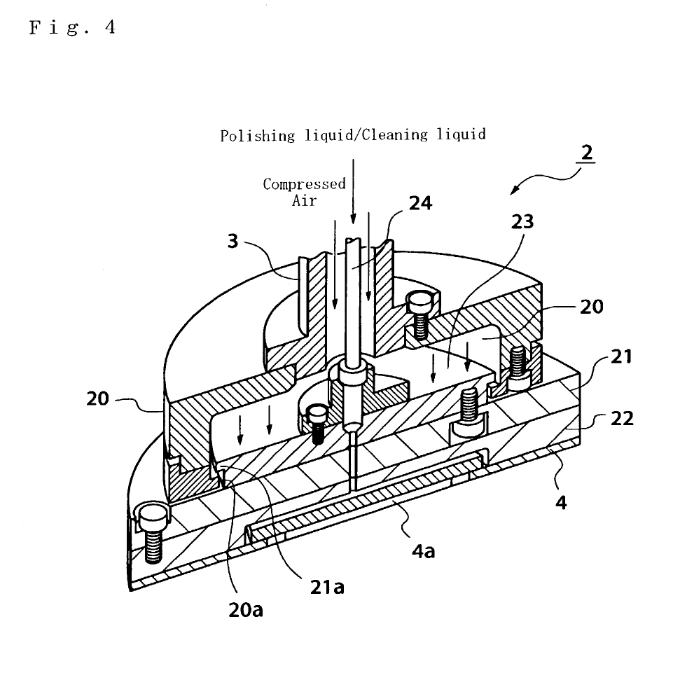

In the polishing head 2 shown in FIG. 4, the head 2 is devised so that the protruding edge 21a of the substrate 21 is supported on the flange part 20a of a pressurizing cylinder 20, and the polishing pad (annular polishing cloth) 4 is held on the substrate 21 via a polishing cloth attachment plate 22. A diaphragm 23 is installed inside the pressurizing chamber 20b of the pressurizing cylinder 20, and compressed air is pressure-fed into the interior of the pressurizing chamber 20b via the interior of the spindle shaft 3. The substrate 21 is supported by this pressure so that the substrate 21 is free to swing in three dimensions (X, Y and Z), and the pad 4 is held parallel to the surface of the wafer.

A supply pipe 24 for the polishing liquid or cleaning liquid is installed in the center of the head 2, and the tip end of this pipe faces the back surface of the annular body of the polishing pad (while avoiding the central bored part 4a of the polishing pad), so that the polishing liquid or etching liquid is supplied to the surface of the metal layer of the substrate via the annular body.

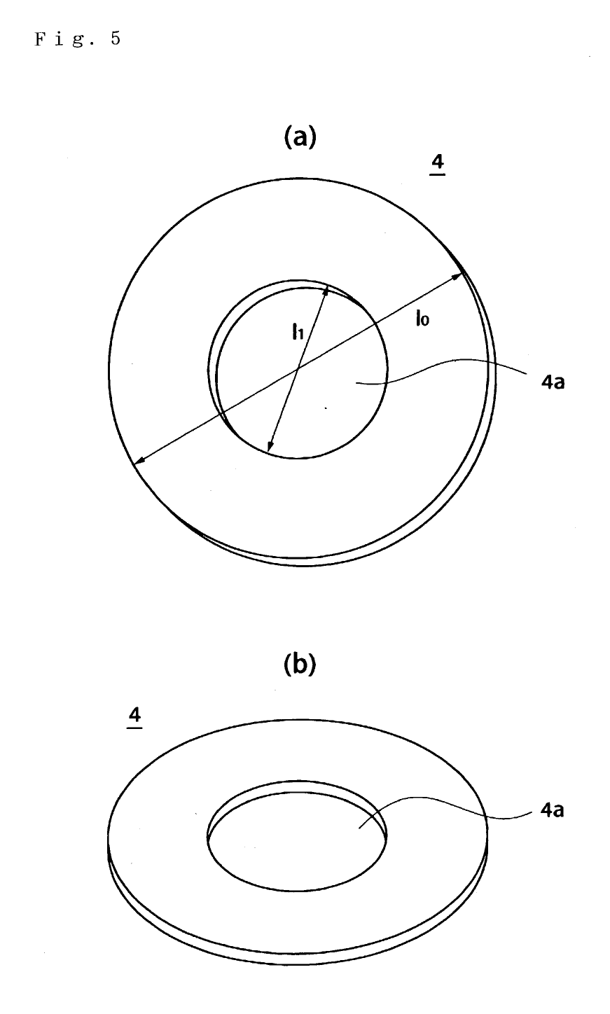

Next, examples of the polishing pads used in the present invention will be described. The polishing pads 4 shown in FIG. 5 include (a) a circular annular polishing pad that is used in the present invention, and (b) an elliptical annular polishing pad that is used in the present invention. The internal diameter li of the hole that is bored through each annular polishing pad is 5 to 75%, preferably 30 to 50%, of the external diameter lo of the polishing pad.

In cases where the polishing pad is a circular annular polishing pad, the ratio of the external diameter of the polishing pad to the external diameter of the substrate w that has the metal film that is to be polished is 0.5 to 0.75 times. In cases where the polishing pad is an elliptical annular pad, this ratio is 0.35 to 0.40 times in the case of the diameter along the short axis, and 0.5 to 0.75 times in the case of the diameter along the long axis.

A hard foam urethane sheet, polyester fiber nonwoven fabric, felt, polyvinyl alcohol fiber nonwoven fabric, nylon fiber nonwoven fabric, or a material in which a urethane resin solution is flow-spread on such a nonwoven fabric and is then foamed and hardened, etc., is used as the pad material. The thickness of the pad is 1 to 7 mm. Furthermore, laminates of the above-mentioned materials may also be utilized.

A slurry which contains the following materials is used as the polishing agent liquid: (a) solid abrasive grains of colloidal alumina, fumed silica, cerium oxide or titania, etc., at the rate of 0.01 to 20 wt %, (b) an oxidizing agent such as copper nitrate, iron citrate, manganese peroxide, ethylenediaminetetraacetic acid, hexacynao-iron, hydrofluoric acid, fluorotitanic acid, dipersulfate, ammonium fluoride, ammonium hydrogen difluoride, ammonium persulfate or hydrogen peroxide at the rate of 1 to 15 wt %, (c) a surfactant at the rate of 0.3 to 3 wt %, (d) a pH adjusting agent, and (e) a preservative, etc. (see Japanese Patent Application Kokai No. H6-313164, Japanese Patent Application Kokai No. H8-197414, Japanese Patent Application Tokuhyo No. H8-510437, Japanese Patent Application Kokai No. H10-67986, and Japanese Patent Application Kokai No. H10-226784, etc.).

Polishing agent slurries that are suitable for the polishing of metals such as copper, copper-titanium, copper-tungsten and titanium-aluminum can be obtained from Fujimi Incorporated, Rodel Nitta Company, Cabot Corporation (U.S.A.) and Rodel, Inc. (U.S.A.).

The process whereby a wafer that has a metal film on top of an insulating layer is polished using the above-mentioned chemical mechanical polishing apparatus is performed as follows:

1) The wafer w1 is removed from the cassette 9 by the arm of the conveying robot 10 and is placed on the temporary placement stand 11 with the metal film surface facing upward. Here, the back surface of the wafer is cleaned, and the wafer is then conveyed into the wafer loading zone s1 of the indexing table 12 by the conveying robot, and is suction-chucked by the chucking mechanism 12a.

2) The indexing table 12 is caused to rotate 90 degrees in the clockwise direction, so that the wafer w1 is conducted into the first polishing zone s2. The spindle shaft 3 is lowered so that the polishing pad 4 attached to the head 2a is pressed against the wafer w1, and chemical mechanical polishing of the wafer is performed by causing the spindle shaft 3 and the shaft of the chucking mechanism to rotate. During this period, a new wafer w2 is placed on the temporary placement stand, and is conveyed into the wafer loading zone s1 and suction-chucked by the chucking mechanism 12b.

In the case of CMP working of a wafer, the polishing agent liquid is supplied to the back surface of the annular body 4 via the supply pipe 24 installed in the hollow part of the spindle shaft 3 at the rate of 10 to 100 ml/min. The rpm of the wafer that is suction-chucked on the chucking table is 200 to 800 rpm, preferably 300 to 600 rpm, and the rpm of the polishing pad is 400 to 3000 rpm, preferably 600 to 1000 rpm.

During CMP working, the polishing pad is caused to perform a reciprocating swinging motion in the left-right direction (the direction of the X axis) by means of a ball screw, over a distance extending between points located at a width of 10 to 60 mm to the left of the center point of the wafer and a width of 10 to 60 mm to the right from the outer circumference of the wafer. The reciprocating swinging motion of the polishing pad is set so that in a case where the swinging speed of the polishing pad when the outer circumference of the polishing pad is positioned between the center point and outer circumference of the wafer is taken as the reference speed, the swinging speed of the polishing pad in the vicinity of the center point of the wafer is slowed, and the swinging speed in the outer circumferential portions of the wafer is accelerated, so that dishing is evened out. For example, in a case where the width of the swinging motion is 40 mm, and the swinging speed when the outer circumference of the polishing pad is positioned between the center point and outer circumference of the wafer is 300 mm/min, the swinging speed of the polishing pad in the vicinity of the center point of the wafer is set at 260 mm/min, and the swinging speed of the polishing pad in the outer circumferential portions of the wafer is set at 320 mm/min.

The pressure with which the polishing pad is pressed against the wafer surface is 50 to 150 g/cm².

When chemical mechanical polishing in the first polishing zone s2 has been performed for a desired period of time, the spindle shaft 3 is raised and retracted to the right, and is conducted onto a pad cleaning mechanism 5. Here, abrasive grains and metal polishing debris adhering to the pad surface are removed by a rotating brush 6 while a high-pressure jet of water is caused to jet from a nozzle 5b. Then, the polishing pad is again conveyed to the right, and is caused to wait in the polishing zone s2.

3) The indexing table is caused to rotate 90 degrees in the clockwise direction, so that the polished wafer w1 is conducted into the second polishing zone s3. Then, the spindle shaft 3 is lowered so that the polishing pad 4 attached to the head 2b is pressed against the roughly polished wafer w1, and finishing chemical mechanical polishing of the wafer is performed by causing the spindle shaft 3 and the shaft of the chucking mechanism to rotate. After this finishing polishing is completed, the spindle shaft 3 is raised and retracted to the right; the polishing pad attached to the head 2b is cleaned by the cleaning mechanism 5, and is then again conveyed to the right and caused to wait in the second polishing zone s3.

During this period, a new wafer w3 is placed on the temporary placement stand, conveyed into the wafer loading zone s1, and suction-chucked by the chucking mechanism 12c. Furthermore, in the first polishing zone s2, rough chemical mechanical polishing of the wafer w2 is performed.

4) The indexing table 12 is caused to rotate 90 degrees in the clockwise direction, so that the polished wafer w1 is conducted into the unloading zone s4. Next, the wafer that has been subjected to finishing polishing is conveyed to the temporary placement stand 15 by the unloading conveying robot 13, and the back surface of this wafer is cleaned. Afterward, this wafer is conducted by the conveying robot 13 to a conveying mechanism that utilizes a belt conveyor, and a cleaning liquid is blown onto the pattern surface of the polished wafer from a nozzle 17 so that the pattern surface is cleaned; the wafer is then conducted to the next process.

During this period, a new wafer w4 is placed on the temporary placement stand; this wafer is conveyed into the wafer loading zone s1, and is suction-chucked by the chucking mechanism 12d. Furthermore, rough chemical mechanical polishing of the wafer w3 is performed in the first polishing zone s2, and finishing chemical mechanical polishing of the wafer w2 is performed in the second polishing zone s3.

5) The indexing table 12 is caused to rotate 90 degrees in the clockwise direction, after which operations similar to those of the above-mentioned processes 2) through 4) are repeated, so that chemical mechanical polishing of the wafers is performed.

In the above example, the chemical mechanical polishing was divided into a first rough polishing process and a second finishing polishing process in order to shorten the throughput time; however, it would also be possible to perform CMP working in a single stage, or to further shorten the throughput time by dividing the polishing into three stages, i.e., rough polishing, intermediate polishing and finishing polishing. In cases where a three-stage CMP working process is adopted, s1 is used as a zone for both wafer loading and wafer unloading, s2 is used as a first polishing zone, s3 is used as a second polishing zone, and s4 is used as a third polishing zone.

Furthermore, in regard to the polishing pad material, the materials of the first polishing pad and second polishing pad may be varied.

Naturally, the chemical mechanical polishing apparatus of the present invention may also be used for the removal of the insulating layer film from a substrate in which an insulating layer film is formed on top of a metal pattern, or for the removal of the P-TEOS film layer from an STI.

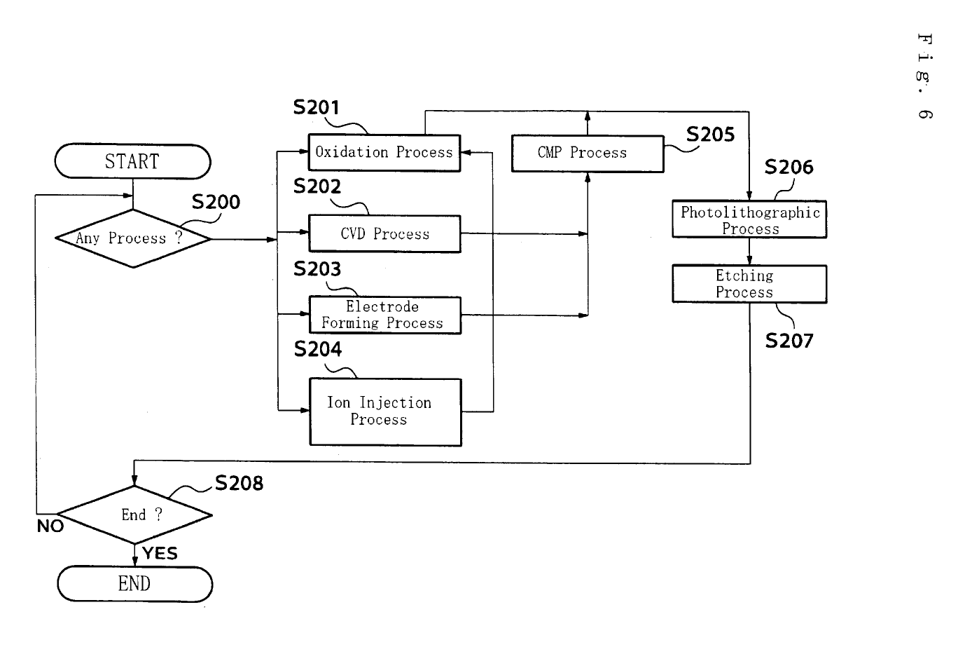

FIG. 6 is a flow chart which illustrates the semiconductor device manufacturing process. The semiconductor device manufacturing process is started, and in step S200, an appropriate processing step is first selected from steps S201 through S204 described below. The processing then proceeds to one of steps S201 through S204 in accordance with this selection.

Step S201 is an oxidation process in which the surface of the wafer is oxidized. Step S202 is a CVD process in which an insulating film is formed on the surface of the wafer by CVD, etc. Step S203 is an electrode formation process in which electrodes are formed on the wafer by a process such as vacuum evaporation. Step S204 is an ion injection process in which ions are injected into the wafer.

Following the CVD process or electrode formation process, the processing proceeds to step S205. Step S205 is a CMP process. In this CMP process, planarization of the interlayer insulating film, or the formation of a damascene, etc., by polishing of the metal film on the surface of the semiconductor device is performed using the polishing apparatus of the present invention.

Following the CMP process or oxidation process, the processing proceeds to step S206. Step S206 is a photolithographic process. In this photolithographic process, coating of the wafer with a resist, burning of a circuit pattern onto the wafer by exposure using an exposure apparatus, and development of the exposed wafer, are performed. Furthermore, the next step S207 is an etching process in which portions other than the developed resist image are removed by etching, and the resist is then stripped so that the resist that has become unnecessary following the completion of etching is removed.

Next, in step S208, a judgement is made as to whether or not all of the required processes have been completed. If the required processes have not been completed, the processing returns to step S200, and the above-mentioned steps are repeated, so that a circuit pattern is formed on the wafer. When it is judged in step S208 that all of the processes have been completed, the working process is ended.

In the semiconductor device manufacturing method of the present invention, the chemical mechanical polishing apparatus of the present invention is used in the CMP process; accordingly, market requirements regarding dishing and erosion in the CMP process are satisfied, so that the yield of the CMP process is improved. As a result, the present invention has the following effect: namely semiconductor devices can be manufactured at a lower cost than is possible in conventional semiconductor device manufacturing methods.

Furthermore, the polishing apparatus of the present invention may also be used in the CMP process of semiconductor device manufacturing processes other than the semiconductor device manufacturing process described above.

(Embodiment 1)

Substrate polishing was performed in which a silicon substrate with a diameter of 300 mm in which a copper film was formed on top of a silicon oxide insulating film was used as the substrate, a copper film polishing slurry manufactured by company A supplied at the rate of 50 ml/min was used as the polishing agent, an annular pad consisting of a polyurethane resin disk with an external diameter of 150 mm in which the central portion was bored through at a diameter of 50 mm was used as the polishing pad, and the automatic chemical mechanical polishing apparatus shown in FIG. 1 was used as the polishing apparatus.

The rpm of the substrate chucking table was set at 400 rpm, the rpm of the polishing pad was set at 700 rpm, and the pressure of the polishing pad applied to the substrate was set at 1.4 psi (100 g/cm²). The left-right swinging width was set at 54 mm (with the starting point of swinging set 27 mm to the left inside from the external diameter of the substrate, and 27 mm to the right inside from the center point of the substrate). The swinging speed was set at 260 mm/min on the outer circumferential side of the substrate from 27 mm to the left inside of the external diameter of the substrate, and at 320 mm/min at the center point of the substrate from 27 mm to the right inside of the center point of the substrate, and polishing was performed at a speed of 300 mm/min between these areas (throughput time 3.0 minutes), thus producing a wafer with a pattern width of 150 μm. As a result, the dishing was 18 nm.

### COMPARATIVE EXAMPLE 1

A wafer with a pattern width of 150 μm was obtained by performing substrate polishing under the same conditions as in Embodiment 1, except that a disk-form pad consisting of a polyurethane resin with an external diameter of 150 mm in which the central portion was not bored through was used as the polishing pad. The dishing was 241 nm, which was far greater than that seen in the embodiment.

### COMPARATIVE EXAMPLE 2

A wafer with a pattern width of 150 μm was obtained by performing substrate polishing under the same conditions as in Embodiment 1, except that an elliptical disk-form pad consisting of a polyurethane resin with a long-axis diameter of 160 mm and a short-axis diameter of 80 mm in which the central portion was not bored through was used as the polishing pad.

The dishing was 124 nm, which was smaller than that seen in Comparative Example 1, but far greater than that seen in Embodiment 1.

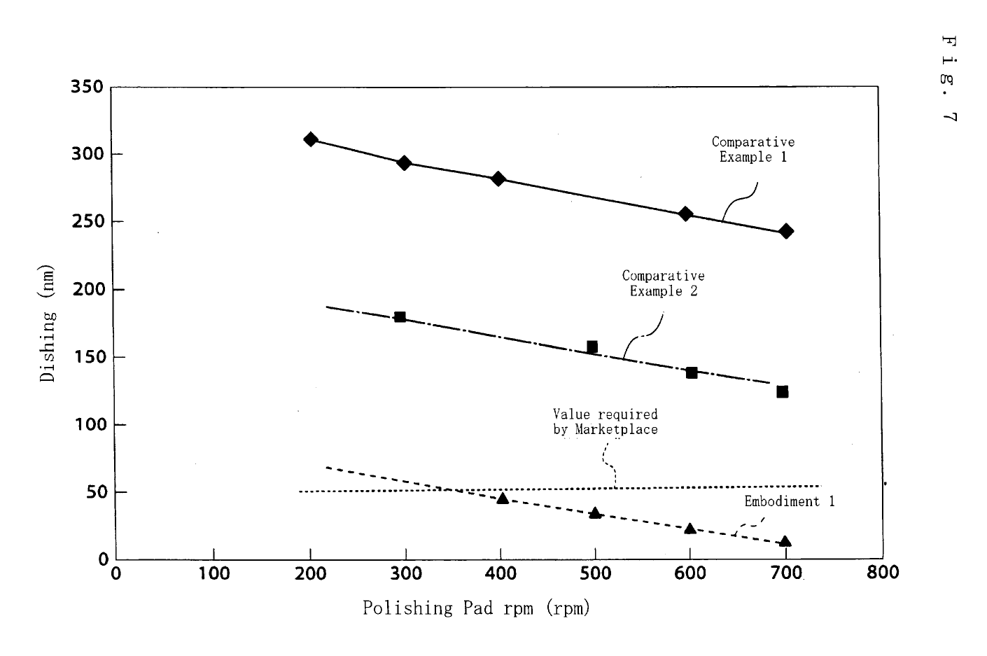

FIG. 7 shows the correlation between the rpm of the polishing pad and the dishing of the wafer that was seen when polishing was performed in Embodiment 1, Comparative Example 1 and Comparative Example 2 with only the rpm of the polishing pad varied, and with all other conditions the same. In the case of Embodiment 1, dishing reaches the value required by the marketplace if the rpm of the polishing pad is set at approximately 350 rpm or greater; however, dishing does not reach the value required by the marketplace in either Comparative Example 1 or Comparative Example 2, even if the rpm of the polishing pad is increased to 700 rpm.

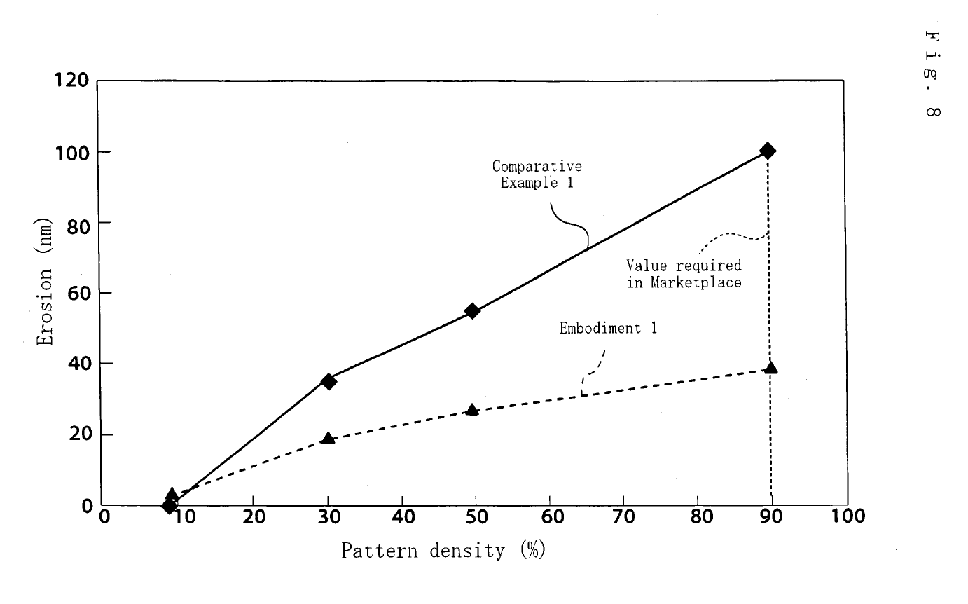

FIG. 8 shows the correlation between erosion and pattern density with respect to the insulating layer that was seen when substrates having different pattern densities with respect to the insulating layer were polished under the respective conditions indicated in Embodiment 1 and Comparative Example 1.

It is seen from this figure that erosion is suppressed to a smaller value in Embodiment 1 than in Comparative Example 1, even if the pattern density is large.

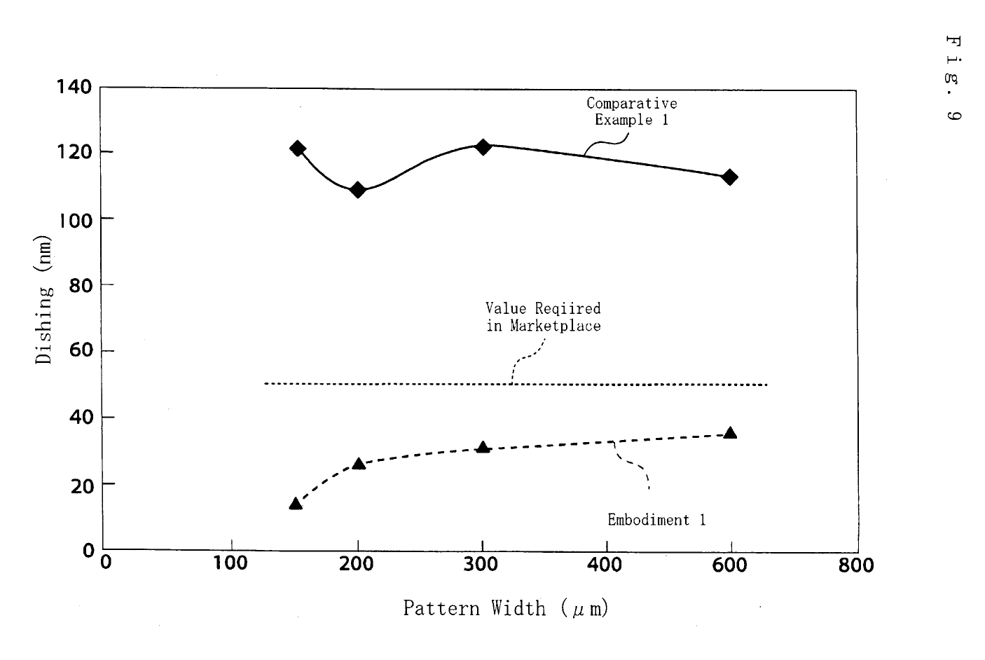

FIG. 9 shows the correlation between pattern width and dishing that was seen when substrates with different pattern widths were polished under the conditions indicated in Embodiment 1 and Comparative Example 1. It is seen from FIG. 9 that for pattern widths of 150 to 600 μm, the dishing values are all equal to or better than the value required by the marketplace in the case of Embodiment 1, while the dishing values do not reach the value required by the marketplace in Comparative Example 1.

(Embodiment 2)

Polishing was performed for 4 minutes under the same conditions as in Embodiment 1, except that an STI substrate (trench width 250 μm, trench density 50%) in which a 15 nm silicon oxide insulating layer was formed on the surface of a silicon substrate with a diameter of 300 mm, a 200 nm silicon nitride insulating layer was formed on top of this silicon oxide insulating layer, and an 800 nm P-TEOS layer was formed on top of this silicon nitride insulating layer, was used as the wafer, and a polishing agent slurry containing 1 wt % cerium oxide abrasive grains manufactured by Company B was used as the polishing agent.

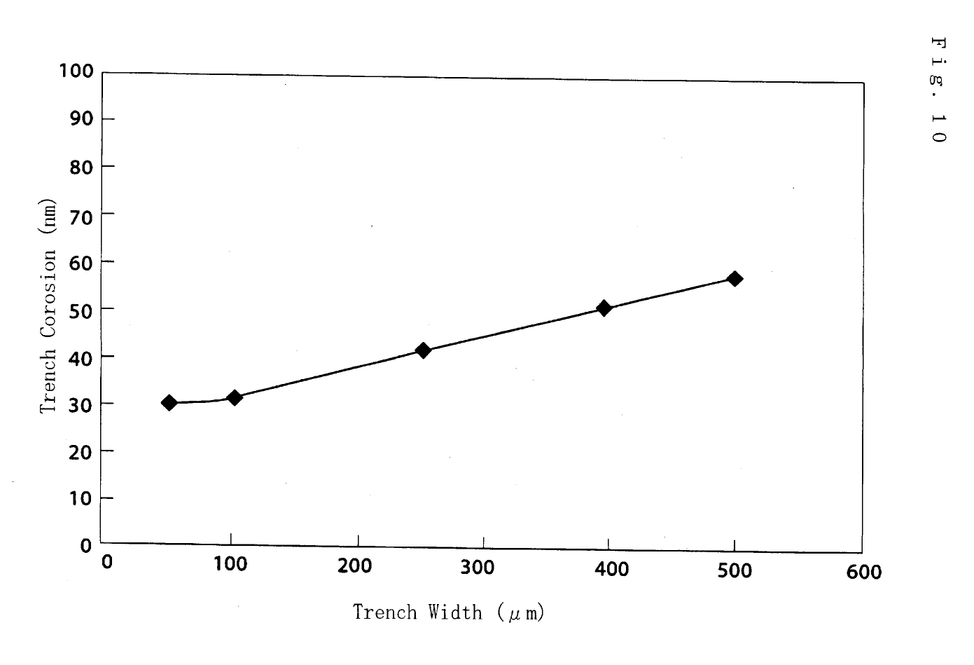

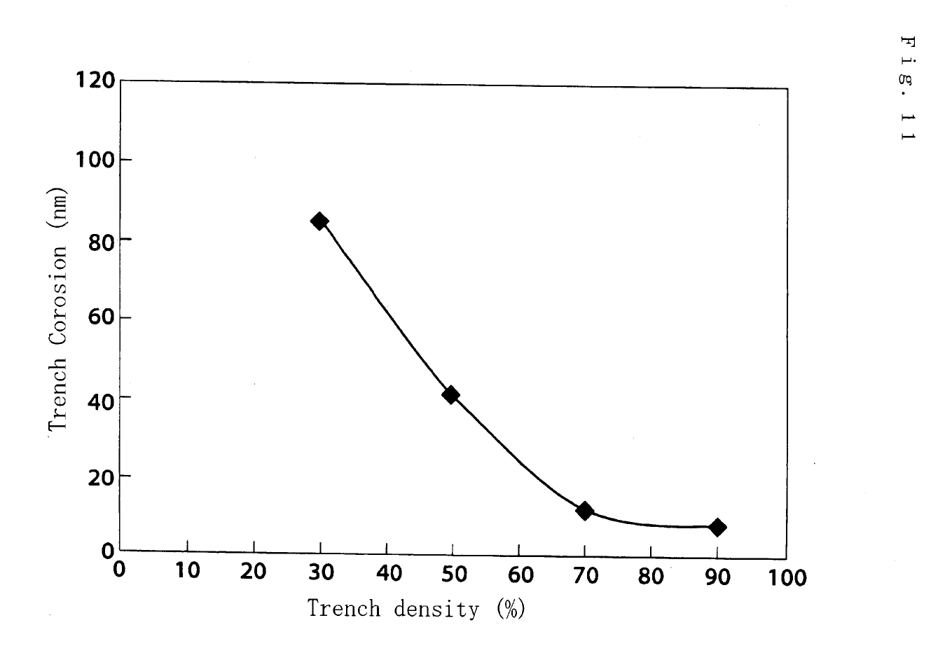

As a result, the erosion of the trenches was 41 nm, and the amount of SiN that was removed was 12 nm. FIG. 10 shows the correlation between trench width and erosion that was obtained when polishing was performed under the same conditions with the trench width varied, and FIG. 11 shows the correlation between trench density and erosion that was obtained when polishing was performed under the same conditions with the trench density varied.

It is seen from these figures that even if trench erosion occurs, polishing can be stopped within the silicon nitride insulating layer without exposing the silicon oxide film in the case of a pattern with a trench width of 250 μm and a trench density of 50%. Furthermore, it is seen that even in regions with a large trench width or regions with a small trench density, in which trench erosion proceeds to a greater extent, polishing can be stopped within the silicon nitride insulating film without exposing the silicon oxide film.

Industrial Applicability

The chemical mechanical polishing apparatus and polishing pad of the present invention are useful for the removal of metal films formed on top of insulating layers, the removal of insulating layer films from the surfaces of substrates in which insulating layer films are formed on top of metal film patterns, and the removal of P-TEOS layers from STI (shallow trench insulators). Furthermore, the semiconductor device manufacturing method of the present invention is useful for manufacturing semiconductor devices that have fine patterns.

1. A chemical mechanical polishing apparatus which polishes a substrate by causing relative movement of this substrate and a polishing pad in a state in which a polishing liquid is interposed between this polishing pad and the substrate, wherein the shape of the above-mentioned polishing pad is an annular shape in which the central portion of a circle or ellipse is bored through in a circular or elliptical shape that has a smaller diameter.

2. A chemical mechanical polishing apparatus in which a substrate that has a metal film is held on a chucking table with the metal film surface facing upward, the surface of a polishing pad pasted on an attachment plate which is shaft-supported on a spindle shaft that has a shaft core oriented in the vertical direction is pressed against the above-mentioned substrate in relative terms with free polishing abrasive grains interposed, and the substrate and polishing pad are caused to rub against each other so that at least a portion of the metal film on the surface of the substrate is removed, wherein this apparatus comprises a raising-and-lowering mechanism for the above-mentioned polishing pad, and a feeding mechanism that causes the above-mentioned polishing pad to perform a reciprocating motion in the left-right direction, the shape of the above-mentioned polishing pad is an annular shape in which the central portion of a circle or ellipse is bored through in a circular or elliptical shape that has a smaller diameter, and the diameter of the polishing pad is smaller than the diameter of the substrate.

3. A chemical mechanical polishing apparatus in which an STI substrate that has a P-TEOS film is held on a chucking table with the P-TEOS film surface facing upward, the surface of a polishing pad pasted on an attachment plate which is shaft-supported on a spindle shaft that has a shaft core oriented in the vertical direction is pressed against the above-mentioned substrate in relative terms with free polishing abrasive grains interposed, and the substrate and polishing pad are caused to rub against each other so that at least a portion of the P-TEOS film on the surface of the substrate is removed, wherein this apparatus comprises a raising-and-lowering mechanism for the above-mentioned polishing pad, and a feeding mechanism that causes the above-mentioned polishing pad to perform a reciprocating motion in the left-right direction, the shape of the above-mentioned polishing pad is an annular shape in which the central portion of a circle or ellipse is bored through in a circular or elliptical shape that has a smaller diameter, and the diameter of the polishing pad is smaller than the diameter of the substrate.

4. A chemical mechanical polishing apparatus in which a substrate that has an insulating layer film formed on top of a metal film pattern is held on a chucking table with the insulating layer film surface facing upward, the surface of a polishing pad pasted on an attachment plate which is shaft-supported on a spindle shaft that has a shaft core oriented in the vertical direction is pressed against the above-mentioned substrate in relative terms with free polishing abrasive grains interposed, and the substrate and polishing pad are caused to rub against each other so that at least a portion of the insulating layer film on the surface of the substrate is removed, wherein this apparatus comprises a raising-and-lowering mechanism for the above-mentioned polishing pad, and a feeding mechanism that causes the above-mentioned polishing pad to perform a reciprocating motion in the left-right direction, the shape of the above-mentioned polishing pad is an annular shape in which the central portion of a circle or ellipse is bored through in a circular or elliptical shape that has a smaller diameter, and the diameter of the polishing pad is smaller than the diameter of the substrate.

5. The chemical mechanical polishing apparatus according to any one of claims 2 through 4, wherein the above-mentioned feeding mechanism has the function of varying the movement speed of the above-mentioned polishing pad in the left-right direction in accordance with the position of the above-mentioned polishing pad with respect to the above-mentioned substrate.

6. A chemical mechanical polishing apparatus in which a substrate whose maximum external diameter is approximately the same as or smaller than the maximum external diameter of the polishing pad is polished by causing the relative movement of the above-mentioned polishing pad and the above-mentioned substrate in a state in which a polishing liquid is interposed between the above-mentioned polishing pad and the above-mentioned substrate wherein the shape of the above-mentioned polishing pad has an annular shape.

7. The chemical mechanical polishing apparatus according to claim 6, wherein the shape of the above-mentioned polishing pad is an annular shape in which the central portion of a circle or ellipse is bored through in a circular or elliptical shape that has a smaller diameter.

8. The chemical mechanical polishing apparatus according to any one of claims 1 through 7, wherein the internal diameter of the hole that is bored through the above-mentioned polishing pad is 5 to 75% of the external diameter of the above-mentioned polishing pad.

9. A polishing pad which has an annular shape, and whose maximum dimension is approximately the same as or smaller than the maximum dimension of the substrate that is polished.

10. The polishing pad according to claim 9, wherein the shape of this polishing pad is an annular shape in which the central portion of a circle or ellipse is bored through in a circular or elliptical shape that has a smaller diameter.

11. The polishing pad according to claim 10, wherein the diameter of the above-mentioned portion that is bored through is 5 to 75% of the external diameter of the above-mentioned polishing pad.

12. A semiconductor device manufacturing method comprising a process in which the surface of a semiconductor wafer is planarized using the chemical mechanical polishing apparatus of any one of the inventions according to claims 1 through 8.
